(19) United States
(12) Patent Application Publication
(10) Pub. No.: US 2016/0291075 A1
(43) Pub. Date: Oct. 6, 2016

(54) METHOD AND SYSTEM FOR DIAGNOSE OF A SOLENOID VALVE

(71) Applicant: SCANIA CV AB, Södertälje (SE)

(72) Inventor: Joakim Sommansson, Grödinge (SE)

(21) Appl. No.: 15/034,812

(22) PCT Filed: Dec. 10, 2014
(86) PCT No.: PCT/SE2014/051475

§ 371 Date: May 5, 2016

(30) Foreign Application Priority Data
Dec. 13, 2013 (SE) 1351492-2

(51) Int. Cl. G01R 31/06; F16K 31/06; F16K 37/00; G01R 19/25

(52) U.S. Cl. CPC G01R 31/06; G01R 19/2506; F16K 31/0675; F16K 37/0083

(57) ABSTRACT

Disclosed is a method for diagnosis of a solenoid valve, wherein said solenoid valve comprises a solenoid and a moveable valve element, wherein said moveable valve element is moveable between a first state and a second state, wherein the movement from said first state to said second state is achieved through supply of current to said solenoid. The method comprises: to, at a first time, where the current through said solenoid is increasing, determine a first derivative for said current, to, at a second time, following said first time, and where the current through said solenoid is increasing, determine a second derivative for said current, and to, based on a comparison between said first derivative and said second derivative, diagnose said solenoid valve.

### FIELD OF THE INVENTION

The present invention relates to solenoid valves (magnet valves) and in particular to a method for diagnosis of a solenoid valve according to the preamble of claim 1. The invention also relates to a system and a vehicle, as well as a computer program and a computer program product, which implement the method according to the invention.

### BACKGROUND OF THE INVENTION

Solenoid valves (magnet valves) are used in a large number of application areas, and may e.g. be used for controlled regulation of supply of fluids in the form of gas or liquid to any applicable type of system.

For example, solenoid valves may be used for control of different functions in pneumatic and/or hydraulic systems, such as for control of flows to cylinders, air or liquid-operated engines, etc. Solenoid valves may e.g. also be used in sprinkler systems for automatic irrigation, in machines such as washing machines, dishwashers, direct acting solenoid valves for use in controlling dampers/actuators between two states, e.g. such as the choke function in outboard motors, etc., and also in a large number of other areas.

Furthermore, solenoid valves are used e.g. in vehicles where such valves may be arranged to be used for control of different functions, where gas and/or liquid is to be controlled. For example, such solenoid valves may be used in the commonly occurring compressed air systems, especially in heavy goods vehicles, or at e.g. the supply of fuel or other liquids to an after-treatment system for after-treatment (purification) of exhausts resulting from a combustion engine. Such solenoid valves may also be used in many other types of functions.

Overall, there is a large number of application areas for solenoid valves. Regardless of the area of use, however, it is important that the solenoid valve functions in the manner intended.

Solenoid valves usually comprise a moveable valve element, wherein said moveable valve element is moveable between a first state and a second state, and wherein the movement of the valve element is controlled through supply of current to a solenoid. A commonly occurring error in a solenoid valve is that the intended movement is not carried out in the manner intended. A solenoid valve may for example be used to alternate between two states, such as an open and a closed state, where, in the event of an error, the intended movement is not carried out completely, or at all, or slower than intended.

### SUMMARY OF THE INVENTION

One objective of the present invention is to provide a method for diagnosis of a solenoid valve, which may determine whether the solenoid valve functions in the manner intended. This objective is achieved with a method according to claim 1.

The present invention relates to a method for diagnosis of a solenoid valve, wherein said solenoid valve comprises a solenoid and a moveable valve element, wherein said moveable valve element is moveable between a first state and a second state, wherein movement from said first state to said second state is achieved through supply of current to said solenoid. The method comprises:

at a first point in time, where a current through said solenoid is increasing, to determine a first derivative for said current,

at a second point in time, following said first point in time, and where the current through said solenoid is increasing, to determine a second derivative for said current, and

based on a comparison between said first derivative and said second derivative, to diagnose said solenoid valve.

According to the above, one error occurring in solenoid valves consists of the movement intended by the moveable valve element not being carried out at all, or being carried out incompletely. It is therefore desirable to be able to diagnose whether an expected movement is actually carried out, whereat the solenoid valve's function may also be diagnosed.

Such diagnosis may be carried out by determining whether the moveable valve element is in movement during an expected time period, in which case the solenoid may be deemed to function correctly.

This method for detection of the solenoid valve's function assumes, however, that the moveable valve element initiates the movement at one end position, and that the movement is completed at the other end position. Furthermore, it is a requirement that the movement always takes equally long in identical conditions, such as with respect to temperature, voltage and the force acting against the moveable valve element's movement.

A malfunctioning solenoid valve may thus seem to function perfectly if a movement is ongoing during the predetermined time period, while in practice only a part of the movement is being carried out, e.g. because of increased friction in connection with the movement, although the measured switching time still fulfils the applicable conditions.

Such a method may also identify errors, even though no malfunction prevails in practice. For example, the conditions at the solenoid valve may vary over time, e.g. with respect to temperature and/or air humidity, with the consequence that switching times may vary due to such external factors.

There are also diagnostic methods based on the current that flows through the solenoid at valve switching. For example, the sign for the derivative for the current that flows through the solenoid may be monitored, so that a diagnosis may be carried out based on the alternation in the sign of the derivative. Such changes in signs may, however, be very difficult to detect, and therefore the diagnosis is not always reliable.

The present invention also uses the derivative for the current flowing through the solenoid at diagnosis, but in a manner providing an improved diagnosis compared to other technologies. According to the present invention, the derivative for the current at two consecutive points in time are compared, when the current through the solenoid is increasing. When the moveable valve element has carried out the desired movement by way of supply of current to the solenoid, an air gap is closed, and as a consequence the magnetic circuit's features change, so that the resistance to the current increase through the solenoid also changes, as does the speed at which the current increases. This is used by the present invention by comparing current derivatives in order to determine, whether the expected change in the derivative of the current has arisen. If this is the case, the solenoid valve may be deemed to function correctly, while it may otherwise be deemed to malfunction.

The first of said consecutive points in time consists of a point in time before the moveable valve element's switching, and may e.g. consist of a certain time as of the supply of current to the solenoid and consist of a time where the current has stabilised. The point in time may also be arranged to consist of some applicable point in time before the current has reached an amperage, which is sufficient for the valve switching to occur.

The second point in time consists of a point in time following after the first point in time. For example, said second point in time may be arranged to consist of a point in time, at which the movement of the valve element from said first state to said second state is assumed to have occurred.

Said second point in time may e.g. consist of a point in time, at which the absence of a movement from said first state to said second state represents a malfunctioning valve. For example, there may be a predetermined maximum time within which switching should have occurred, in order for a correct function to be deemed to exist, and the second point in time may thus consist of a point in time when at least such a time period has lapsed.

Said second time may also consist of a time at least corresponding to an expected expenditure of time, in order for the valve element to be able to undergo switching to said second state. Factors such as required amperage for switching and maximum permitted switching time may e.g. be empirically determined, or may be determined with the use of applicable calculations.

Further characteristics of the present invention and advantages thereof will be described in the detailed description of example embodiments set out below and in the enclosed drawings.

### BRIEF DESCRIPTION OF THE DRAWINGS

FIGS. 1A-B schematically show an example of a solenoid valve in a non-activated and an activated state, for which the present invention may be used.

FIG. 2 schematically shows an example method according to one embodiment of the present invention

FIG. 3 shows an example of a current change for a solenoid in the solenoid valve according to FIGS. 1A-B.

FIG. 4 shows an example of a control device, in which the present invention may be implemented.

FIGS. 5A-B schematically show another example of a solenoid valve, for which the present invention may be applied.

### DETAILED DESCRIPTION OF PREFERRED EMBODIMENTS

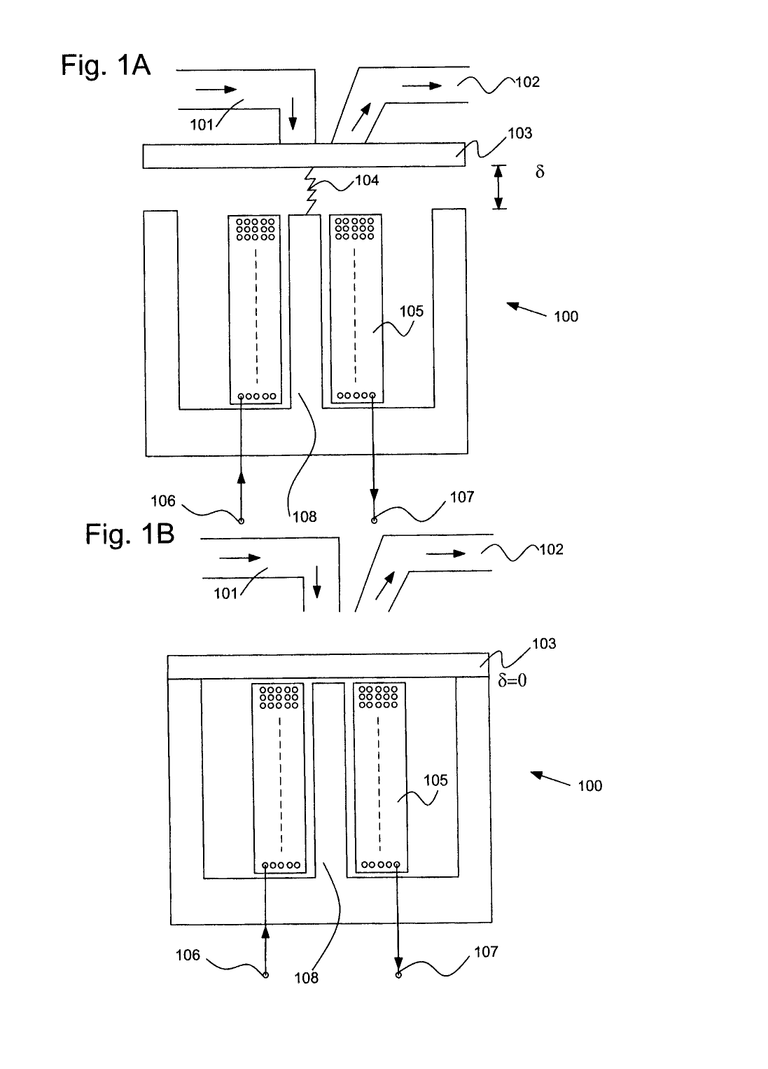

FIG. 1A shows an example of a cross-section of a generally cylindrical solenoid valve 100, for which the present invention maybe applied. As mentioned above, solenoid valves may assume a large number of appearances, and function in different ways, which is why the solenoid valve displayed in FIG. 1A merely constitutes one non-limiting example, and the present invention is applicable for all types of solenoid valves where a moveable valve element is moved through the action of a force, where the force is created by means of a current being led through a solenoid. The displayed solenoid valve may e.g. be used as an injector in an after-treatment system, for after-treatment of exhausts resulting from a combustion engine, where fuel or another fluid is supplied to the after-treatment system through the injector.

The solenoid valve 100 displayed in FIG. 1A comprises an inlet 101, to which fluid regulated by the solenoid valve, such as a fluid or a gas, is supplied. The solenoid valve 100 also comprises an outlet 102, which consists of a regulated outlet, where a connection between inlet and outlet may be opened/closed selectively. Such control is achieved by way of manoeuvring a moveable valve element 103, often referred to as a “plunger”, which, in the present example, keeps the connection between the inlet and the outlet closed when the solenoid valve is in a resting state, i.e. when a solenoid 105 is not powered-up. At rest, the connection between inlet and outlet is kept closed by way of a spring force, which is achieved by a spring 104. The reverse may also be the case, i.e. the connection between the inlet and the outlet may be kept open in a solenoid which is not powered-up. Furthermore, the connection may be kept closed by way of fluid pressure, wherein thus, instead of a spring force, the pressure of the fluid is overcome by a magnetic force as set out below.

For solenoid valves of the type displayed, with the objective of securing the function of the solenoid valve, a solution may be applied where a fluid is allowed to pass from the inlet side of the moveable valve element to the side of the moveable valve element 103 which faces away from the inlet/outlet, wherein, in a closed state, a decompressed moveable valve element 103 is obtained with respect to the fluid, so that a relatively small spring force Fₛ is required from the spring 104, in order to achieve a closure of the connection between the inlet and the outlet when the solenoid is without power.

The function of the solenoid valve is critically dependent on the moveable element 103 behaving in an expected manner, i.e. moving in an expected manner, when a movement is to be carried out in order to shift the state of the solenoid valve 100.

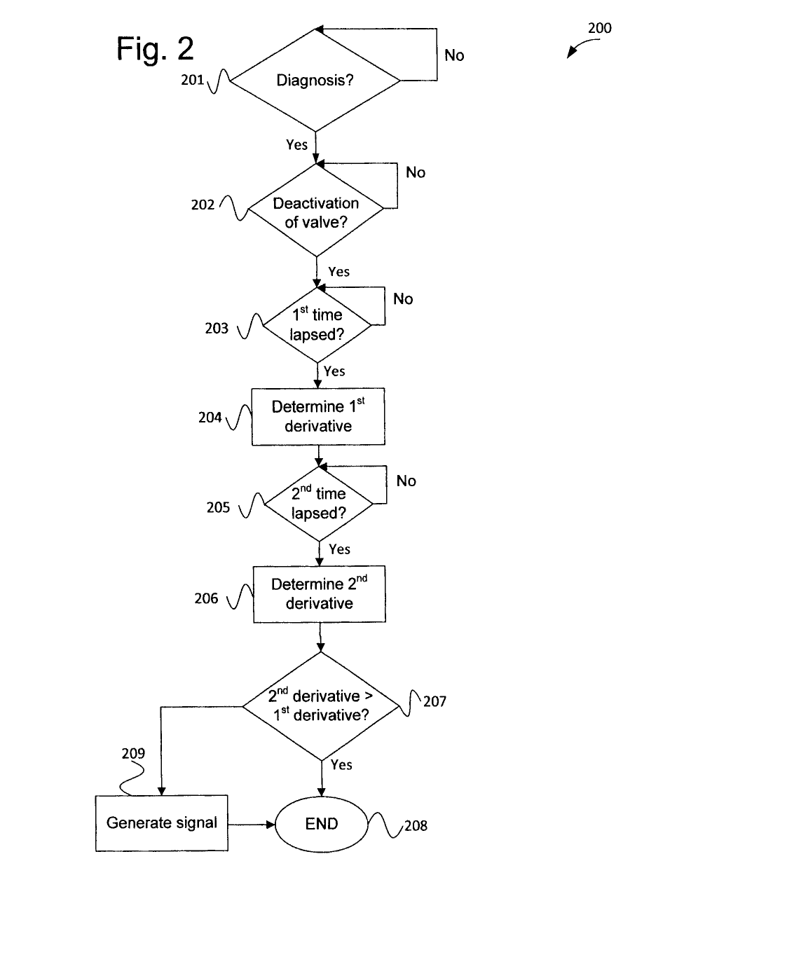

The present invention relates to a method to ensure that a desired movement is actually carried out. One example method 200 according to the present invention is displayed in FIG. 2, where the method starts at step 201, with determining whether the function of the solenoid valve 100 should be diagnosed. This may e.g. be arranged to be carried out every time the solenoid valve 100 is activated, with applicable intervals, when a malfunction is suspected, or for another applicable reason. When the solenoid valve 100 is to be diagnosed, the method continues to step 202, where it is determined whether the solenoid valve 100 is activated, i.e. in this case, whether a voltage v₀ is applied over the solenoid 105, so that a current starts to flow through the solenoid 105.

The method remains at step 202 until the solenoid valve 100 is activated. When the solenoid valve 100 is activated, the method continues to step 203, where it is determined whether a first time T1 has lapsed according to the below, following which the method continues to step 204, where a first current rate of change, i.e. the derivative of the current, is determined. This first current rate of change (derivative) is thus determined after a first period of time T1, where this first period of time T1 may be arranged to constitute a time lapsed after the solenoid was energised and a current thus started to flow through the solenoid. This delay before the derivative is determined entails that transients at the connecting moment may be avoided. According to one embodiment, however, no such delay is carried out.

Movement of the moveable valve element 103, and thus shifting, in the present example, from a closed state to an open state for connection between said inlet 101 and outlet 102 is achieved by way of an electromagnetic force Fₘ acting on the moveable valve element 103.

The electromagnetic force Fₘ is generated by energising the solenoid 105 via connecting elements 106, 107. The solenoid 105 is wound around a core 108 of magnetic material, such as an iron core.

When a voltage is applied over the solenoid 105 via the connecting elements 106, 107, a current iₘ will begin to flow through the solenoid 105 and thus give rise to a magnetic field, where the current iₘ may be described as the relationship:

$${i}_{m} = \frac{{v}_{0}}{R} - \frac{{v}_{0}}{R} {e}^{- tR / L} \qquad ( equation 1 )$$

where

v₀ constitutes the voltage over the solenoid 105,

R constitutes the resistance through the solenoid 105,

L constitutes the inductance of the magnetic circuit, whereat the magnetic circuit consists of the iron core 108, the moveable valve element 103 and the air gap δ. The current is thus zero at the connecting moment, and rises gradually afterwards. When the current begins to flow through the solenoid, an electromagnetic force, Fₘ, is continuously built up, which is dependent on and increases with an increase of the current iₘ, and which acts on the moveable valve element 103 in such a manner that it strives to move the moveable valve element in a direction towards the iron core, in order to thus reduce the air gap δ between the iron core 108 and the moveable valve element 103.

As long as the opposing spring force Fₛ exceeds the electromagnetic force induced with the current Fₘ, no movement of the moveable valve element will, however, occur, but as soon as the electromagnetic force Fₘ exceeds the spring force Fₛ, the moveable valve element will start a movement in a direction towards the iron core 108. When the movement of the moveable valve element 103 in a direction towards the iron core 108 starts, the air gap δ is reduced, which entails that the electromagnetic force Fₘ, which, as is known, is strongly dependent on the air gap distance between the moveable valve element and the iron core 108, increases and as a consequence the movement of the moveable valve element becomes increasingly faster until the air gap δ is eliminated, and contact between the iron core 108 and the moveable valve element 103 occurs. This state is displayed in FIG. 1B.

When the air gap δ is closed through the movement of the moveable valve element 103, and δ thus is equal to zero, the features of the electro-magnetic circuit change, which thus changes the speed at which the current through the solenoid increases. The present invention uses this relationship at the diagnosis of the function of the solenoid valve 100.

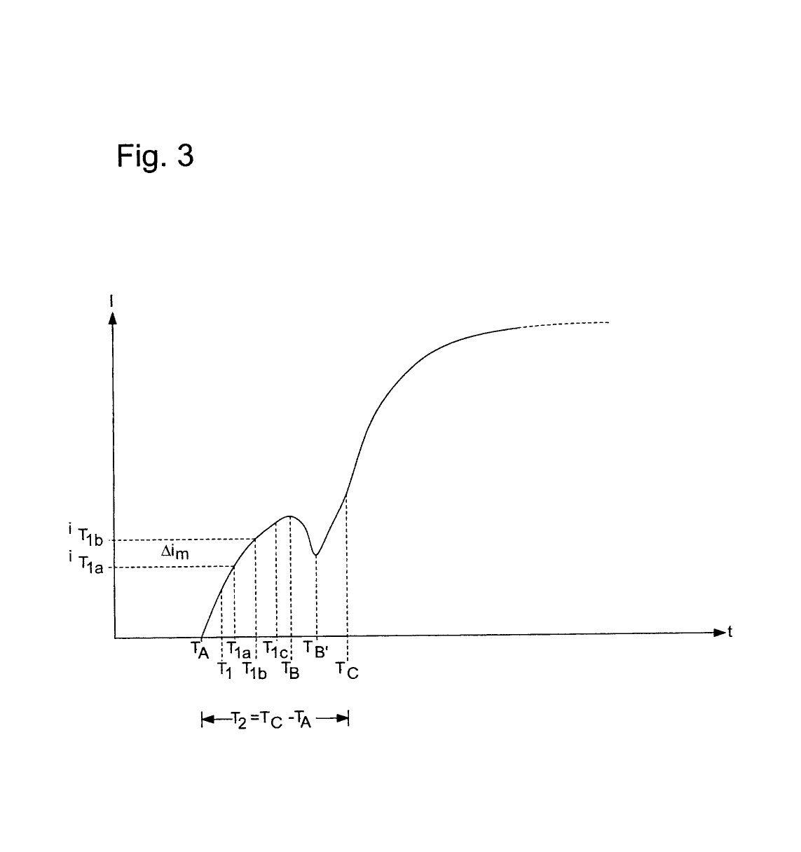

One example of the change of the current in connection with switching of the solenoid valve 100 is displayed in FIG. 3. When a voltage is applied over the connections at the time T_{A}, a current begins to flow through the solenoid 105. This current will, according to the above, increase over time according to equation 1, where the increase, at least after possible initial type transients, will be substantially constant while the magnetic force is built up, but will still be below the force Fₘ which is required to overcome the spring force Fₛ. This also means that the current derivative will be substantially constant during this time period.

When a voltage v₀ thus has been applied to the solenoid, a first derivative for the current

$$\frac{d {i}_{T 1}}{d t}$$

is, according the above, determined in step 204, which may thus be arranged to be carried out only when a first time T₁ has lapsed since the solenoid 105 was activated. According to one embodiment, however, the determination is carried out directly when the voltage has been applied.

Furthermore, in step 204 the current derivative may be determined as an average value of two or more determinations of the current derivative. The current derivative may be determined in an applicable manner, such as

$$\frac{Δ {i}_{m}}{Δ t} ,$$

where Δiₘ may e.g. be determined as i_{T1b}-i_{T1a}, and Δt as T_{1b}-T₁ₐ. The current may thus be determined at several points in time T_{1b}, T_{1c}, etc., so that current derivatives for the respective time period T_{1b}-T₁ₐ, T_{1c}-T_{1b}may be determined, and also over longer time periods, such as T_{1c}-T₁ₐwherein an average value for the derivative for iₘ may be determined based on such determinations. Obviously, an applicable number of determinations may be carried out, such as more or fewer, where according to one embodiment only one determination of the derivative for iₘ is carried out, respectively, before and after an (expected) valve switching. For example, some applicable, e.g. empirically determined, sampling speed may be applied, so that it may be determined that a desired number of current determinations, and thus derivatives, may be carried out, respectively, before and after a valve switching.

When a first derivative for the current iₘ thus has been determined in step 204, the method continues to step 205, where it is determined whether a second time T2 (=TC-TA in FIG. 3) has lapsed since the voltage v₀ was applied to the solenoid 105. This second time T2 may consist of a time period that corresponds to or exceeds the time period, which is expected to be required before the moveable valve element has been brought into contact with the iron core 105 by way of the force Fₘ, and thus has completely opened the passage between the inlet and the outlet. The magnetic force Fₘ exceeds the spring force Fₛ when the current through the solenoid 105 has achieved a current i_{fm}, which occurs at the time TB in FIG. 3. The switching between the state displayed in FIG. 1A and FIG. 1B happens very quickly, however, since the force Fₘ acting on the moveable valve element increases with the reduced distance to the iron core 108, which thus entails that the closer the moveable valve element 103 comes to the iron core 108, the higher the force Fₘ it is exposed to, and thus it moves at a higher speed.

The valve switching will thus happen very quickly, and take place between TB and TB′ in FIG. 3.

The present invention thus uses the change arising in the magnetic circuit when the air gap δ has been closed. According to the above, the air gap δ has a great impact on the magnetic circuit, and therefore also on the inductance L of the solenoid. Thus the parameters in equation 1 will also be impacted, and as a consequence the current's derivative will change. This is illustrated in FIG. 3.

When said second time T2 has thus lapsed, the method continues to step 206, where a derivative

$$\frac{d {i}_{T 2}}{d t}$$

for the current through the solenoid is again determined. This derivative

$$\frac{d {i}_{T 2}}{d t}$$

may be determined in a similar manner as is described for

$$\frac{d {i}_{T 1}}{d t}$$

above, and thus may e.g. consist of an average value based on several determinations of the derivative, which are carried out after the time T2. When a derivative

$$\frac{d {i}_{T 2}}{d t}$$

at the time T2 thus has been determined, the method continues to step 207 where

$$\frac{d {i}_{T 2}}{d t}$$

is compared with

$$\frac{d {i}_{T 1}}{d t} .$$

As may be seen in the figure, after the air gap has been closed the derivative will be higher compared to when an air gap still prevails, which thus depends on the inductance change arising when the air gap is closed. The inductance change will, as such, be non-linear during the movement of the moveable valve element 103, but as explained above, this movement is usually very fast, and may, according to one embodiment, be considered instantaneous, so that the change in current occurring while the valve shifts its state need not be considered according to the present invention. This change in current may also be very difficult to detect. The fundamental appearance of the current change at valve switching is displayed in FIG. 3. The present invention determines, however, derivatives during periods when the current is increasing, so that the invention is not sensitive to whether or not current changes during the actual switching are detected. According to one embodiment, the second derivative is determined at a time where the valve's switching of state is assumed to be completed, and according to one embodiment changes of the current derivative may be ignored during the valve's switching of state, e.g. by continuously determining the derivative of the current, wherein the second derivative

$$\frac{d {i}_{T 2}}{d t} ,$$

according to the present invention, is not considered to be determined until the derivative at two or more consecutive determinations, when the current is increasing, differ from each other by more than some applicable value.

In step 207 it is determined whether

$$\frac{d {i}_{T 2}}{d t}$$

exceeds

$$\frac{d {i}_{T 1}}{d t} ,$$

and if that is the case, the method is completed at step 208, since the valve is then deemed to function correctly, as the derivative has increased in the expected manner. If, on the other hand,

$$\frac{d {i}_{T 2}}{d t}$$

does not exceed

$$\frac{d {i}_{T 1}}{d t} ,$$

i.e. is equal with

$$\frac{d {i}_{T 1}}{d t}$$

or smaller than

$$\frac{d {i}_{T 1}}{d t} ,$$

the method continues to step 209, where a signal, such as an error indication, is generated. This error indication may be carried out in an applicable manner, e.g. by activating an applicable error code in a control system controlling the function of the solenoid valve.

According to one embodiment,

$$\frac{d {i}_{T 2}}{d t}$$

must only exceed

$$\frac{d {i}_{T 1}}{d t}$$

in order for the solenoid valve to be deemed to function correctly, while, according to one embodiment, it is a requirement that

$$\frac{d {i}_{T 2}}{d t}$$

exceeds

$$\frac{d {i}_{T 1}}{d t}$$

by at least a first value, in order for the valve to be deemed to function correctly.

When the valve switching has occurred, the voltage over the solenoid may be reduced, since the power, and hence the current that is required when the air gap is closed is substantially lower compared to when there is an air gap, as is known. By reducing the voltage so that the current is also reduced, or at least is no longer permitted to increase, e.g. heat losses may be reduced.

By way of summary, the present invention provides a method for diagnosis of a solenoid valve which may determine, with good certainty, whether a desired function is performed. The invention also has the advantage that, since only one increase in derivatives need to be detected, a solution is obtained, which is independent of changes in the solenoid valve's ambient conditions. For example, the solenoid's resistance and inductance depend on many parameters, such as air humidity, temperature, etc., which means that the current may increase with different derivatives from one time to another, even though the solenoid valve functions entirely correctly. Solenoid valves may e.g. be installed in vehicles which may be driven in surroundings where the temperature and/or air humidity vary greatly, and where the temperature at the specific position where the solenoid valve is installed may vary greatly while the vehicle is travelling, e.g. because of heating by e.g. the engine and/or the exhaust system.

The present invention is insensitive to such changes in ambient parameters, since the current derivative will continue to increase after the air gap has been closed, wherein the invention is therefore insensitive to specific values, and wherein relative parameters may thus be used.

Furthermore, the present invention has been exemplified above in connection with a specific example of a solenoid valve. According to prior art, solenoid valves may be built in several other ways, e.g. with respect to how the opening/closing occurs. The present invention is applicable for all solenoid valves, which otherwise meet the determinations according to the enclosed claims.

The invention is thus applicable for all solenoid valves which, during normal function, display a behaviour where the derivative for an applied current increases, when the desired movement of a moveable valve element has been completed.

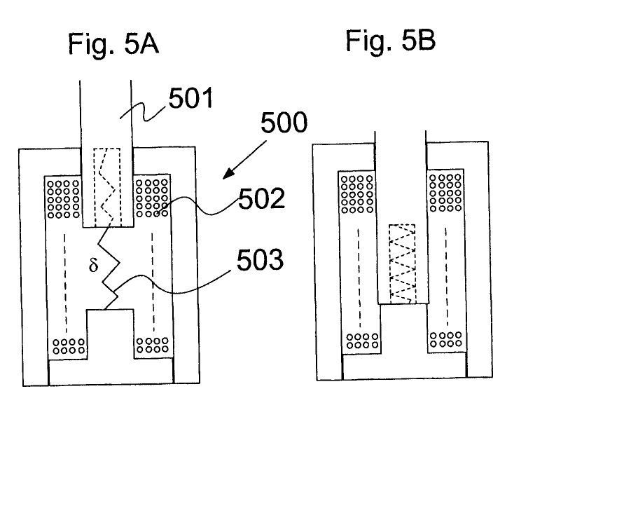

Furthermore, the control carried out by the solenoid valve may be of different types, e.g. arranged to close a passage at activation instead of opening it, as described above. A solenoid valve may also comprise more than two ports, e.g. three, so that readjustment of the valve may e.g. switch between opening of a passage from one entrance to a first and a second exit respectively, alternatively switching between a first and a second entrance, respectively, to an exit. The invention is thus applicable also for such valves. One example of a commonly occurring type of solenoid valve 500 is displayed in FIGS. 5A-B. FIG. 5A shows a cross-section of a generally cylindrical valve 500 with a moveable valve element 501, and a solenoid 502. In FIG. 5A the solenoid valve is in a resting state, e.g. the solenoid 502 is not energised, and the moveable valve element is kept at one of its end positions with a spring 503. The spring is arranged to run inside the moveable valve element to facilitate closure of the air gap δ. In the state displayed in FIG. 5A, the solenoid valve 500 may e.g. be arranged to keep a fluid connection open or closed.

When the solenoid is energised and the spring force generated by the spring 503 is overcome, the air gap δ is closed, see FIG. 5B, whereat a change of the current's resistance occurs in the manner described above, and which may also be detected according to the present invention.

The method according to the present invention may advantageously be implemented in a control device in a control system that controls the solenoid valve's function. Such control devices are often controlled by programmed instructions. These programmed instructions typically consist of a computer program, which, when executed in the control device, causes the control device to carry out the desired control action, such as the method steps according to the present invention.

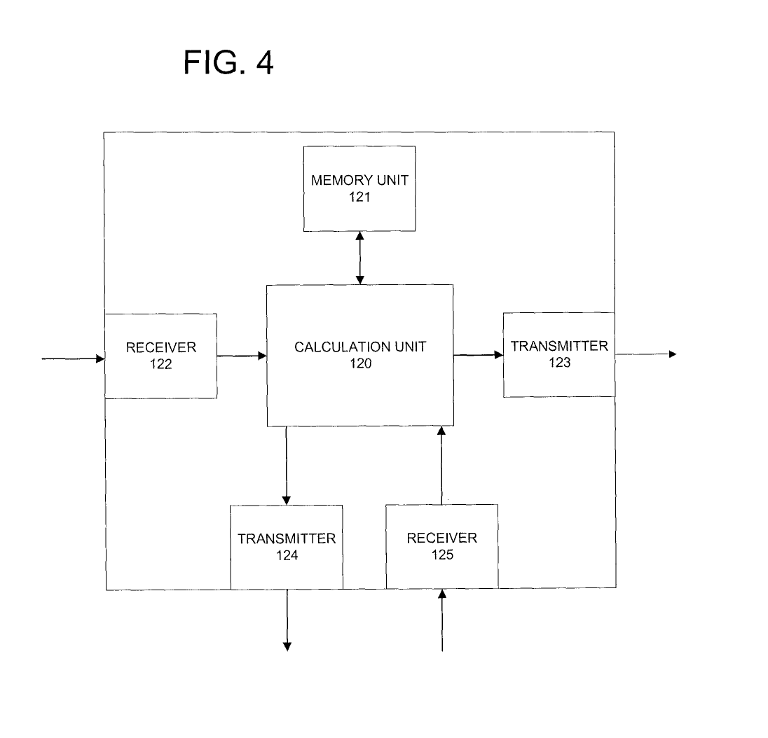

The computer program is usually a part of a computer program product, where the computer program product comprises an applicable storage medium 121 (see FIG. 4), with the computer program stored on said storage medium 121. Said program may be stored in a non-volatile manner on said storage medium. Said digital storage medium 121 may e.g. consist of any from the following group: ROM (Read-Only Memory), PROM (Programmable Read-Only Memory), EPROM (Erasable PROM), Flash, EEPROM (Electrically Erasable PROM), a hard disk unit, etc., and may be set up in or in combination with the control device, where the computer program is executed by the control device. By changing the computer program's instructions, the vehicle's behaviour may thus be adjusted in a specific situation.

One example control device is displayed schematically in FIG. 4, and the control device in turn may comprise a calculation device 120, which may consist of e.g. a suitable type of processor or microcomputer, e.g. a circuit for digital signal processing (Digital Signal Processor, DSP), or a circuit with a predetermined specific function (Application Specific Integrated Circuit, ASIC). The calculation unit 120 is connected to a memory unit 121, which provides the calculation unit 120 with e.g. the stored program code and/or the stored data that the calculation unit 120 needs in order to be able to carry out calculations, e.g. to determine whether an error code must be activated. The calculation unit 120 is also set up to store interim or final results of calculations in the memory unit 121.

Further, the control device is equipped with devices 122, 123, 124, 125 for receiving and sending of input and output signals. These input and output signals may contain waveforms, pulses or other attributes which, by the devices 122, 125 for the receipt of input signals, may be detected as information for processing by the calculation unit 120. The devices 123, 124 for sending output signals are arranged to convert the calculation result from the calculation unit 120 into output signals for transfer to other parts of the vehicle's control system and/or the component(s) for which the signals are intended. Each one of the connections to the devices for receiving and sending of input and output signals, respectively, may consist of one or several of the following: a cable; a data bus, such as a CAN (Controller Area Network) bus, a MOST (Media Oriented Systems Transport) bus, or any other bus configuration; or of a wireless connection.

Other embodiments of the method and the system according to the invention are available in the claims enclosed hereto. It should also be noted that the system may be modified according to various embodiments of the method according to the invention (and vice versa) and that the present invention is in no way limited to the above embodiments of the method according to the invention, but relates to and comprises all embodiments within the scope of the enclosed independent claims.

1. A method for diagnosis of a solenoid valve, wherein said solenoid valve comprises a solenoid and a moveable valve element, wherein said moveable valve element is moveable between a first state and a second state, wherein movement from said first state to said second state is achieved by supply of current to said solenoid, wherein the method comprises:
at a first time (T1), before the movement from said first state to said second state, when a current through said solenoid is increasing, to determine a first derivative
$$( \frac{d {i}_{T 1}}{d t} )$$
for said current,
at a second time (T2), following said first time, and when the current through said solenoid is increasing, to determine a second derivative
$$( \frac{d {i}_{T 2}}{d t} )$$
for said current, and
based on a comparison between said first derivative
$$( \frac{d {i}_{T 1}}{d t} )$$
and said second derivative
$$( \frac{d {i}_{T 2}}{d t} ) ,$$
to diagnose said solenoid valve.

2. The method according to claim 1, also comprising, at said diagnosis of said solenoid valve, to determine whether said solenoid valve functions correctly or malfunctions.

3. The method according to claim 1, wherein said second time (T2) constitutes a time after the movement of the valve element from said first state to said second state.

4. The method according to claim 1, wherein said second time (T2) is a time, at which the absence of a movement from said first state to said second state represents a malfunctioning valve.

5. The method according to claim 1, wherein said second time (T2) constitutes a time, at which the movement of the valve element from said first state to said second state is assumed to have occurred.

6. The method according to claim 1, wherein said second time constitutes a time, at least corresponding to an expected time expenditure for the readjustment of the valve element to said second state.

7. The method according to claim 1, further comprising:
to determine whether said second derivative
$$( \frac{d {i}_{T 2}}{d t} )$$
exceeds said first derivative
$$( \frac{d {i}_{T 1}}{d t} ) ,$$
wherein said solenoid valve is deemed to function correctly if said second derivative
$$( \frac{d {i}_{T 2}}{d t} )$$
exceeds said first derivative.

8. The method according to claim 1, also comprising to generate a signal if said first derivative
$$( \frac{d {i}_{T 1}}{d t} )$$
is equal to or exceeds said second derivative
$$( \frac{d {i}_{T 2}}{d t} ) .$$

9. The method according to claim 1, wherein said first time (T1) constitutes a first time (T1) after a current starts to flow through said solenoid, and/or said second time (T2) constitutes a second time (T2) after a current starts to flow through said solenoid.

10. The method according to claim 1, wherein said first derivative
$$( \frac{d {i}_{T 1}}{d t} )$$
and/or second derivative
$$( \frac{d {i}_{T 2}}{d t} )$$
is determined based on two or more consecutive determinations of a current derivative.

11. The method according to claim 10, also comprising to determine derivatives for several time periods (T_{1b}-T₁ₐ, T_{1c}-T_{1b}, T_{1c}-T₁ₐ), wherein a value for said first derivative
$$( \frac{d {i}_{T 1}}{d t} )$$
is determined based on said consecutive determinations.

12. The method according to claim 1, wherein said second time (T2) constitutes a time which is greater than, or equal to, an expected time from the supply of current to said solenoid until the valve element, with a force Fₘ induced by the supply of current to said solenoid, has been brought from said first state to said second state.

13. The method according to claim 1, wherein the movement of said moveable valve element, from said first state to said second state, closes an air gap in a magnetic circuit.

14. The method according to claim 1, also comprising to determine whether said second derivative
$$( \frac{d {i}_{T 2}}{d t} )$$
exceeds said first derivative
$$( \frac{d {i}_{T 1}}{d t} )$$
by at least a first value, and
to generate a signal if said second derivative
$$( \frac{d {i}_{T 2}}{d t} )$$
does not exceed said first derivative
$$( \frac{d {i}_{T 1}}{d t} )$$
by said first value.

15. (canceled)

16. A computer program product comprising a computer-readable medium and a computer program according to claim 15, said computer program being comprised in said computer-readable medium, wherein said computer program is configured to cause a computer to:
at a first time (T1), before the movement from said first state to said second state, when a current through said solenoid is increasing, determine a first derivative
$$( \frac{d {i}_{T 1}}{d t} )$$
for said current.
at a second time (T2), following said first time, and when the current through said solenoid is increasing, determine a second derivative
$$( \frac{d {i}_{T 2}}{d t} )$$
for said current, and
based on a comparison between said first derivative
$$( \frac{d {i}_{T 1}}{d t} )$$
and said second derivative
$$( \frac{d {i}_{T 2}}{d t} ) ,$$
diagnose said solenoid valve.

17. A system for diagnosis of a solenoid valve, wherein said solenoid valve comprises a solenoid and a moveable valve element, wherein said moveable valve element is moveable between a first state and a second state, wherein the movement from said first state to said second state is achieved by supply of current to said solenoid, wherein the system comprises:
an electronic storage device;
at least one electronic processor in communication with said electronic storage device;
at least one module stored in said electronic storage device, executable by the at least one processor, and configured to cause the at least one processor:
to, at a first time (T1), before the movement from said first state to said second state, when a current through said solenoid is increasing, determine a first derivative
$$( \frac{d {i}_{T 1}}{d t} )$$
for said current,
to, at a second time (T2), following said first time, and when the current through said solenoid is increasing, determine a second derivative
$$( \frac{d {i}_{T 2}}{d t} )$$
for said current, and
to, based on a comparison between said first derivative
$$( \frac{d {i}_{T 1}}{d t} )$$
and said second derivative
$$( \frac{d {i}_{T 2}}{d t} ) ,$$
diagnose said solenoid valve.

18. Vehicle comprising a system for diagnosis of a solenoid valve, wherein said solenoid valve comprises a solenoid and a moveable valve element, wherein said moveable valve element is moveable between a first state and a second state, wherein the movement from said first state to said second state is achieved by supply of current to said solenoid, wherein said system comprises:
an electronic storage device;
at least one electronic processor in communication with said electronic storage device;
at least one module stored in said electronic storage device, executable by the at least one processor, and configured to cause the at least one processor:
to, at a first time (T1), before the movement from said first state to said second state, when a current through said solenoid is increasing, determine a first derivative
$$( \frac{d {i}_{T 1}}{d t} )$$
for said current,
to, at a second time (T2), following said first time, and when the current through said solenoid is increasing, determine a second derivative
$$( \frac{d {i}_{T 2}}{d t} )$$
for said current, and
to, based on a comparison between said first derivative
$$( \frac{d {i}_{T 1}}{d t} )$$
and said second derivative
$$( \frac{d {i}_{T 2}}{d t} ) ,$$
derivative diagnose said solenoid valve.
